(19) United States
(12) Patent Application Publication
(10) Pub. No.: US 2022/0314226 A1
(43) Pub. Date: Oct. 6, 2022

(54) TEMPERATURE CONTROL DEVICE AND TEMPERATURE CONTROL SYSTEM

(71) Applicant: BOE TECHNOLOGY GROUP CO., LTD., Beijing (CN)

(72) Inventors: Mengjun HOU, Beijing (CN); Xiangguo MA, Beijing (CN); Zongmin LIU, Beijing (CN); Youxue WANG, Beijing (CN)

(21) Appl. No.: 17/419,807

(22) PCT Filed: Sep. 29, 2020
(86) PCT No.: PCT/CN2020/118717

§ 371 Date: Jun. 30, 2021

(51) Int. Cl. B01L 7/02; G05D 23/19

(52) U.S. Cl. CPC B01L 7/02; G05D 23/1919; B01L 2200/147; B01L 2300/023; B01L 2300/0609; B01L 2300/1844; B01L 2300/1894; B01L 2300/1883; B01L 2400/0644

(57) ABSTRACT

The embodiment of the present disclosure provides a temperature control device and a temperature control system. The temperature control device comprises an object stage, a housing, and at least one temperature control structure. The temperature control structure has a main body portion and a temperature control component, and main body portion defines an air duct, and wherein, the main body portion has a second air inlet and a second air outlet, and the first air inlet is connected to the second air outlet, and the external air enters the air duct defined by the main body portion from the second air inlet of the main body portion, and the air then enters the housing through the second air outlet, and the temperature control component is connected, so as to the main body portion to control the temperature of the air in the air duct.

### TECHNICAL FIELD

The present disclosure relates to the field of chip detection, and particularly relates to a temperature control device and a temperature control system.

### BACKGROUND

In the detection process of various biochips, it is often necessary to control the temperature of the detection process. For example, in the detection process of digital Polymerase Chain Reaction (dPCR) chip, if the temperature control is not accurate, the detection result will be inaccurate.

### SUMMARY

The embodiments of the present disclosure are directed to at least solve one of the technical problems in the prior art and provide a temperature control device. During a chip heating or heat preservation process, the temperature control device can isolate heat transfer between a chip and an external environment by a housing, so as to prevent the temperature of the chip from being affected by the external environment, thereby improving the accuracy of temperature control of the chip. Further, when the chip needs to be temperature controlled, the temperature control device can heat or cool the external air and then send the air into the housing by a temperature control structure, so that the temperature of the chip can be controlled, and then effective temperature control can be realized during a chip detection process.

In a first aspect, an embodiment of the present disclosure provides a temperature control device for controlling the temperature of a chip detection process, wherein the temperature control device comprising:

a object stage for carrying a chip;

a housing provided with a first air inlet and a first air outlet, the object stage is disposed in the housing, and the housing is used for reducing heat transfer between the chip on the object stage and an external environment;

at least one temperature control structure provided with a main body portion and a temperature control component, and the main body portion defines an air duct; wherein the main body portion is provided with a second air inlet and a second air outlet, the second air outlet is connected to the first air inlet, and external air enters the air duct defined by the main body portion from the second air inlet and then enters the housing from the second air outlet; the temperature control component is connected to the main body portion to control the temperature of the air in the air duct.

In the temperature control device according to the embodiment of the present disclosure, since the chip is placed on the object stage in the housing during the chip detection process, it is possible to isolate the heat transfer between the chip and the external environment by the housing during a chip heating or heat preservation process, so as to avoid the chip temperature being affected by the external environment, such that the accuracy of temperature control of the chip can be improved; and when the chip needs to be temperature controlled, after the external air enters the temperature control structure, the temperature control structure can quickly control the temperature of the air, such that the air after the temperature control enters the housing and can quickly control the temperature of the chip, and then can achieve effective temperature control in the chip detection process.

In some examples, the temperature control component is a cooling component or a heating component.

In some examples, the temperature control component comprises at least one refrigeration sheet disposed on a side of the main body portion away from the air duct.

In some examples, the main body portion has at least one side wall defining the air duct; if the main body portion is provided with a plurality of side walls, the refrigeration sheets are one-to-one correspondence with the side walls, and each refrigeration sheet is attached to a side of the corresponding side wall away from the air duct.

In some examples, the refrigeration sheet comprise a semiconductor refrigeration sheet, and the semiconductor refrigeration sheet has a refrigeration surface on a side thereof close to the main body portion and a heat dissipation surface on a side thereof away from the main body portion; the heat dissipation surface is connected with a heat dissipation structure, and the heat dissipation structure is used for cooling the heat dissipation surface.

In some examples, at least one partition sheet is disposed within the air duct defined by the main body portion, the partition sheet separating the air duct into a plurality of sub-air ducts; the extending direction of the separating sheet is the same as the extending direction of the air duct.

In some examples, a plurality of the partition sheets are disposed in the air duct defined by the main body portion, and the plurality of the partition sheets are separated into first partition sheets and second partition sheets; wherein,

the plane of the first partition sheet extends along a first direction, the plane of the second partition sheet extends along a second direction, and the first partition sheet and the second partition sheet are interpenetrated with each other, and the extending direction of the plane of the first partition sheet intersects the extending direction of the plane of the second partition sheet.

In some examples, the side wall of the main body portion and the partition sheet are of an integral structure.

In some examples, the side wall of the main body portion and the partition sheet are made of thermally conductive material.

In some examples, the temperature control structure further comprises: a first fan disposed in the air duct defined by the main body portion, and the first fan is used for sending air in the air duct into the housing.

In some examples, each of the first partition sheets is divided into a first front partition sheet and a first rear partition sheet in a length direction; each of the second partition sheet is separated into a second front partition sheet and a second partition sheet in the length direction;

the temperature control structure further comprises: a first fan disposed between the plurality of first front partition sheets and the plurality of first rear partition sheets, and the first fan is disposed between the plurality of second front partition sheets and the plurality of second rear partition sheets.

In some examples, the temperature control structure further comprises: a first temperature sensor disposed in the air duct defined by the main body portion, and the first temperature sensor is used for detecting the temperature in the air duct.

In some examples, at least one second fan is disposed at the first air outlet, and the second fan is used for exhausting the air inside the housing to the outside.

In some examples, further comprising: an air outlet channel connected with the first air outlet, and an air inlet channel connected between the first air inlet and the second air outlet; wherein,

the air outlet channel and the air inlet channel are connected to the opposite sides of the housing, and the air outlet channel and the air inlet channel extend along opposite directions relative to the central axis of the housing.

In some examples, the housing has an opening at a position corresponding to the object stage, the housing has some distance from the object stage, and a loading valve is disposed at the opening;

the loading valve has opposite first and second ends; the first end of the loading valve is rotatably connected to one side of the opening, and when the loading valve is in a closed state, the second end of the loading valve is in contact with the other side of the opening so as to seal the housing; when the loading valve is in an open state, the object stage can extend out of the housing through the opening.

In some examples, the second end is not higher than the plane of the object stage when the load valve is in a closed state.

In some examples, further comprising: a second temperature sensor disposed in the housing, and the second temperature sensor is disposed close to the object stage, and the second temperature sensor is used for detecting the temperature of the chip on the object stage.

In some examples, a plurality of spring knobs are disposed on the opposite side of a side of the object stage carrying the chip, and if the object stage is placed on an external platform, the spring knobs are used for adjusting the inclination angle of the plane of the object stage carrying the chip relative to the external platform.

In a second aspect, an embodiment of the present disclosure further provides a temperature control system, wherein the temperature control system includes the above temperature control device.

In some examples, further comprising:

a processing unit;

an input device connected to the processing unit, the processing unit sends a control instruction to the temperature control device according to an operation instruction input by the input device so as to control the temperature control device to adjust the temperature; and

a power amplifying unit connected between the processing unit and the temperature control device, and the power amplifying unit is used for outputting control voltage to the temperature control device according to a control instruction sent by the processing unit.

### BRIEF DESCRIPTION OF THE DRAWINGS

FIG. 1 is a schematic structural diagram of an embodiment of a temperature control device according to an embodiment of the present disclosure;

FIG. 2 is a schematic structural diagram of an embodiment of a cooling structure of a temperature control device according to an embodiment of the present disclosure;

FIG. 3 is a schematic structural diagram of an embodiment of a refrigeration sheet of a cooling structure in a temperature control device according to an embodiment of the present disclosure;

FIG. 4 is a side view (taken along G-H in FIG. 3) of an embodiment of a refrigeration sheet of a cooling structure in a temperature control device according to an embodiment of the present disclosure;

FIG. 5 is a schematic internal structural diagram (taken along A-B in FIG. 2) of an embodiment of a cooling structure of a temperature control device according to an embodiment of the present disclosure;

FIG. 6 is a cross-sectional view (taken along C-D in FIG. 2) of an embodiment of a cooling structure of a temperature control device according to an embodiment of the present disclosure;

FIG. 7 is a cross-sectional view of another embodiment of a cooling structure of a temperature control device according to an embodiment of the present disclosure;

FIG. 8 is a schematic structural diagram of another embodiment of a cooling structure of a temperature control device according to an embodiment of the present disclosure;

FIG. 9 is a schematic internal structural diagram (taken along the line E-F in FIG. 8) of another embodiment of a cooling structure of a temperature control device according to an embodiment of the present disclosure;

FIG. 10 is a schematic structural diagram of another embodiment of a temperature control device according to an embodiment of the present disclosure;

FIG. 11 is a schematic diagram of an internal structure of another embodiment of a temperature control device according to an embodiment of the present disclosure;

FIG. 12 is a schematic diagram of a temperature control device according to an embodiment of the present disclosure after a chip is loaded;

FIG. 13 is a side view of another embodiment of a temperature control device according to an embodiment of the present disclosure; and

FIG. 14 is a system diagram of an embodiment of a temperature control system according to an embodiment of the present disclosure.

### DETAILED DESCRIPTION OF THE EMBODIMENTS

To improve understanding of the technical solution of the embodiments of the present disclosure for those skilled in the art, the embodiments of the present disclosure will be described below in detail in conjunction with the accompanying drawings and the detailed description of the embodiments.

The shapes and sizes of the components in the drawings do not reflect the real-life dimensional relationships and ratios of components, but are merely intended to facilitate an understanding of the contents of the embodiments of the present disclosure.

Unless defined otherwise, technical and scientific terms used herein have the ordinary meaning as understood by one of ordinary skill in the art to which the present disclosure belongs. The use of the terms “first”, “second” and the like in the present disclosure do not denote any order, quantity, or importance, but rather are used to distinguished one element from another. Also, the use of the terms “a,” “an,” or “the” and the like do not denote a limitation of quantity, but rather denote the presence of at least one. The words “comprising” or “comprises”, and the like mean that the element or item preceding the word comprises the element or item listed after the word and its equivalent, but does not exclude other elements or items. The terms “connect” or “couple” and the like are not restricted to physical or mechanical connections, but can comprise electrical connections, whether direct or indirect. “upper”, “lower”, “left”, “right” and the like are used only to indicate relative positional relationships, and when the absolute position of the object being described is changed, the relative positional relationships may also be changed accordingly.

The disclosed embodiments are not limited to the embodiments shown in the drawings, but comprise modifications of configurations formed based on a manufacturing process. Thus, the regions illustrated in the drawings have schematic properties, and the shapes of the regions shown in the drawings illustrate specific shapes of regions of elements, but are not intended to be limiting.

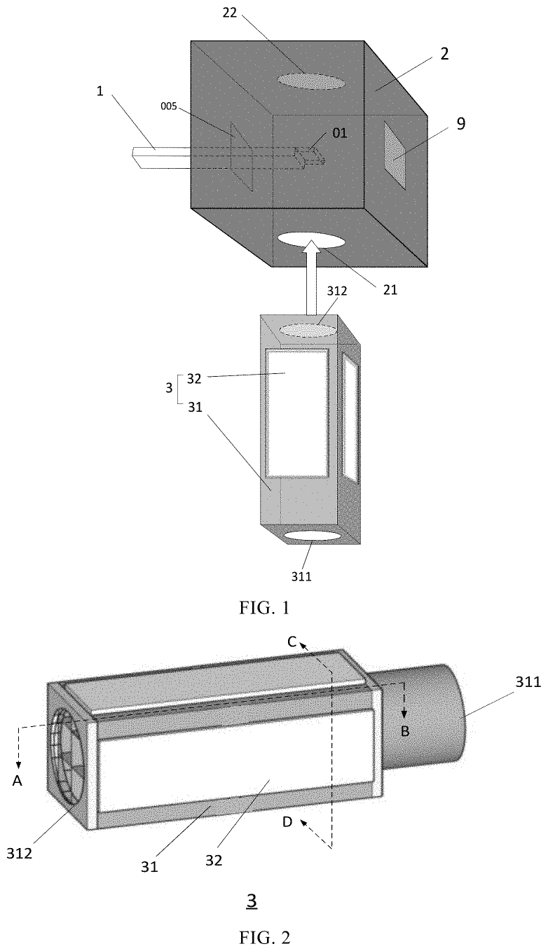

In a first aspect, as shown in FIG. 1, an embodiment of the present disclosure provides a temperature control device for controlling a temperature of a chip detection process. The temperature control device comprises an object stage 1, a housing 2, and at least one temperature control structure 3.

Specifically, as shown in FIG. 1, the object stage 1 is used for carrying a chip, and the object stage 1 is disposed in the housing 2. If the chip is loaded on the object stage 1, the whole chip detection process is performed in the housing 2. The housing 2 can reduce the heat transfer between the chip on the object stage 1 and the external environment, so as to avoid the temperature of the chip from being affected by the external environment. The housing 2 has a first air inlet 21 and a first air outlet 22. The air can enter the housing 2 from the first air inlet 21 to cool the chip on the object stage 1, and the air is then exhausted outside the housing 2 through the first air outlet 22. Further, the temperature control device also comprises at least one temperature control structure 3. The temperature control structure 3 has a main body portion 31 and a temperature control component 32. The main body portion 31 comprises a hollow part, and the hollow part defines the air duct. The main body portion 31 has a second air inlet 311 and a second air outlet 312. The second air outlet 312 of the temperature control structure 3 is connected to the first air inlet 21 of the housing 2. That is, the temperature control structure 3 is connected to the first air inlet 21 of the housing 2. Specifically, the second air outlet 312 of the temperature control structure 3 can be provided with a connector, and the connector is adapted to the first air inlet 21 of the housing 2, so that the connector can be tightly connected to the first air inlet 21. The external air enters the air duct defined by the main body portion 31 from the second air inlet 311 of the main body portion 31 of the temperature control structure 3. The temperature control component 32 is connected to the main body portion 31, and the temperature control component 32 can control the temperature of the air in the air duct defined by the main body portion 31. The air after being temperature controlled then enters the housing 2 through the second air outlet 312 connected to the first air inlet 21 of the housing 2 from the main body portion 31, so as to control the temperature of the chip on the object stage 1 in the housing 2. After that, the air is exhausted from the first air outlet 22 of the housing 2.

Optionally, the temperature control component 31 of the temperature control structure 3 can be a cooling component performing the cooling control on the air in the air duct defined by the main body portion 31. The cooling component 31 can also be a heating component performing the heating control on the air in the air duct defined by the main body portion 31, which is not limited herein. The following description will take the temperature control component 31 as the cooling component for reducing the temperature of the air in the air duct as an example.

It should be noted that the temperature control device can comprise any number of temperature control structures 3. If the temperature control device comprises a plurality of temperature control structures 3, the plurality of temperature control structures 3 are connected to each other. Specifically, in the two adjacent temperature control structures 3, the second air outlet 312 of the first temperature control structure 3 is connected to the second air inlet 311 of the second temperature control structure 3, and then the second air outlet 312 of the temperature control structure 3 located at the outermost is connected to the first air inlet 21 of the housing 2. The more the number of the temperature control structures 3 connected, the more the number of the temperature control structures 3 the air passes through before entering the housing 2, and the more the temperature of the air is reduced. The number of the temperature control structures 3 can be set according to the required temperature of the air. The following description will take the temperature control device comprising one temperature control structure 3 as an example.

In some chip detection processes, it is usually necessary to control the temperature of the chip. For example, in the chip detection process for a digital Polymerase Chain Reaction (dPCR) chip, the chip repeats a plurality of temperature cycles of heating and cooling, and different reactions of DNA polymerase at different temperatures are used to complete the detection. A plurality of reaction chambers in the dPCR chip have high requirements for temperature control during the reaction process of PCR. If the temperature environment, in which the dPCR chip is located when detecting, is not even enough, there will be some temperature differences between the reaction chambers in the dPCR chip, resulting in inaccurate detection results. In the temperature control device according to the embodiment, since the chip is placed on the object stage 1 in the housing 2 during the chip detection process, it is possible to isolate the heat transfer between the chip and the external environment by the housing 2 during a chip heating or heat preservation process, so as to avoid the chip temperature being affected by the external environment, such that the accuracy of temperature control of the chip can be improved. Further, when the chip need be cooled, the air first passes through at least one temperature control structure 3 to be cooled to the desired temperature, and then enters the housing 2, such that the cooled air can quickly reduce the temperature of the chip in the housing 2, so as to improve the cooling efficiency of the chip detection process. The heat transfer with the external environment in the chip detection process is isolated by the housing, so as to provide the heating efficiency of chip detection process, and then the cooling efficiency of chip detection process is improved by temperature control structure 3. Such that, effective temperature control in the chip detection process can be achieved.

In some examples, the housing 2 can be made of insulation material, and the insulation material can be organic insulation material or inorganic insulation material. For example, if the housing 2 is made of an organic insulation material, the material of the housing 2 can comprise polyurethane foam, polystyrene board, polystyrene foam, extruded polystyrene foam, phenolic foam and combinations thereof. If the housing 2 is made of an inorganic insulation material, the material of the housing 2 can comprise ceramic fiber blanket, aluminum silicate felt, alumina, silicon carbide fiber, aerogel felt, glass wool, rock wool, expanded perlite, micro-nano heat insulation, foamed cement and combinations thereof. It should be noted that, the housing 2 can also be made of other materials, which is not limited herein.

It should be noted that, with reference to FIG. 1, the object stage 1 is disposed in the housing 2, and a side of the object stage 1 close to the outside of the housing 2 can be connected to a fixing arm 01. The fixing arm 01 can extend out of the housing 2, and the fixing arm 01 can fix the position of the object stage 1, and the fixing arm 01 can control the movement of the object stage 1 under the driving of an external force.

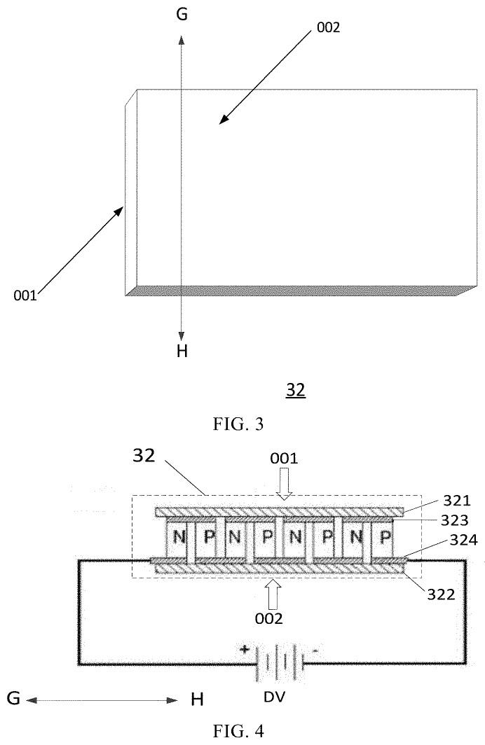

In some examples, as shown in FIGS. 2-4, wherein FIG. 3 is a schematic diagram of the temperature control component 32, and FIG. 4 is a side view of the temperature control component 32 taken along the direction G-H in FIG. 3. The temperature control structure 3 comprises a main body portion 31 and a temperature control component 32. The main body portion 31 is a hollow passage, and the hollow part of the main body portion 31 defines an air duct. Air flows in the air duct of the main body portion 31. The temperature control component 32 is connected to the main body portion 31 and cools the air in the air duct defined by the main body portion 31. The temperature control component 32 can comprise various elements. For example, the temperature control component 32 can comprise at least one refrigeration sheet. The temperature control component 32, which is a refrigeration sheet, is disposed on a side of the main body portion 31 away from the air duct (i.e., the outer side), so as to cool the air by absorbing heat from the air inside the air duct.

In some examples, as shown in FIGS. 3 and 4, the temperature control component 32 specifically comprises a semiconductor refrigeration sheet. The temperature control component 32, which is a semiconductor refrigeration sheet, is attached to a side of the main body portion 31 away from the air duct. A side of the semiconductor refrigeration sheet (the temperature control component 32) close to the main body portion 31 is a refrigeration surface 001, and a side of the semiconductor refrigeration sheet facing away from the main body portion 31 is a heat dissipation surface 002. Specifically, referring to FIG. 4, the temperature control component 32, which is a semiconductor refrigeration sheet, comprises a first insulating substrate 321 and a second insulating substrate 322 that are oppositely disposed. A side of the first insulating substrate 321 is a refrigeration surface 001, and a side of the second insulating substrate 322 is a heat dissipation surface 002. The first insulating substrate 321 is in contact with the main body portion 31. The first insulating substrate 321 has a first conductive layer 323 at a side close to the second insulating substrate 322. The second insulating substrate 322 has a second conductive layer 324 at a side close to the first insulating substrate 321. A plurality of N-type semiconductor units (denoted by “N” in FIG. 4) and a plurality of P-type semiconductor units (denoted by “P” in FIG. 4) are arranged between the first conductive layer 323 and the second conductive layer 324, and the plurality of N-type semiconductor units and the plurality of P-type semiconductor units are arranged in an intersecting manner. The first conductive layer 323 comprises a plurality of separated electrodes, and each electrode connects the adjacent N-type semiconductor unit and P-type semiconductor unit. The second conductive layer 323 also comprises a plurality of separated electrode blocks, and each electrode connects the adjacent N-type semiconductor unit and P-type semiconductor unit. As such, the adjacent N-type semiconductor unit and P-type semiconductor unit are coupled to form a thermocouple pair. When a current passes through the thermocouple pair, the thermocouple pair can generate heat transfer at both ends thereof, and the heat can be transferred from one end to the other end, so that temperature difference is generated to form the refrigeration surface 001 and the heat dissipation surface 002. The second conducting layer 324 can be connected to an external direct-current power supply DV. After the direct-current voltage DV is powered on, electrons start from a negative pole (−), firstly pass through the P-type semiconductor unit, where the electrons absorb heat (the side close to the refrigeration surface 001), and then pass through the first conducting layer 323 to the adjacent N-type semiconductor unit, where the electrons release heat (the side close to the heat dissipation surface 002). Every time electrons passes through an adjacent P-type semiconductor unit and an N-type semiconductor unit, heat is transferred from the refrigeration surface 001 side to the heat dissipation surface 002 side. Therefore, a side of the refrigerating surface 001 (i.e. first insulating substrate 321) of the semiconductor refrigeration sheet is attached to the side of the main body portion 31 away from the air duct. The refrigeration surface 001 of the semiconductor refrigeration sheet can absorb the heat on the side wall of the main body portion 31, and the absorbed heat is transferred to the heat dissipation surface 002 to be released, so as to achieve the refrigerating effect. The first insulating substrate 321 and the second insulating substrate 322 can be insulating substrates made of various materials. For example, the first insulating substrate 321 and the second insulating substrate 322 are both ceramic insulating substrates, which is not limited herein.

Further, in order to maintain the cooling efficiency of the semiconductor refrigeration sheet (the temperature control component 32), it is necessary to reduce the temperature of the heat dissipation surface 002 of the semiconductor refrigeration sheet. Therefore, the heat dissipation surface 002 can be connected to a heat dissipation structure (not shown), and the heat dissipation structure is able to reduce the temperature of the heat dissipation surface 002 of the semiconductor refrigeration surface, so as to maintain the heat transfer efficiency between the heat dissipation surface 002 and the refrigeration surface 001. The heat dissipation structure can comprise various types of heat dissipation elements. For example, the heat dissipation structure can comprise a heat sink and a fan. The heat sink is connected to the heat dissipation surface 002, and the fan is disposed on a side of the heat sink facing away from the heat dissipation surface 002. It should be noted that, the heat dissipation structure can also be other structures, which is not limited herein.

In the temperature control device according to the embodiment of the present disclosure, the main body portion 31 of the temperature control structure 3 has at least one side wall, and the at least one side wall 31 is connected to define an air duct. The main body portion can have various shapes, and correspondingly, the air duct can have various shapes. For example, the main body portion 31 can comprise a side wall, and the side wall encloses the circular main body portion 31 to define a circular air duct, that is, the air duct of the main body portion 31 has a circular cross section. For example, the main body portion 31 can comprise a plurality of side walls, and the plurality of side walls are connected to define the air duct, and the cross section of the air duct of the main body portion 31 can be triangular, rectangular, rhombic, hexagonal and the like, which is not limited herein. For convenience of description, referring to FIG. 2, the main body portion 31 comprises four side walls, and the four side walls are connected to define a rectangular air duct, which is taken as an example, and is not limited herein.

In some examples, as shown in FIGS. 2 and 6, wherein FIG. 6 is a sectional view taken along a direction C-D in FIG. 2. If the main body portion 31 has a plurality of side walls, the temperature control structure 3 has a plurality of refrigeration sheets (temperature control component 32), the refrigeration sheet are in one-to-one correspondence with the side walls of the main body portion 31, and each refrigeration sheet is attached to a side of the corresponding side wall away from the air duct. Taking the main body portion 31 in FIGS. 2 and 6 as an example, the main body portion 31 has four side walls. The four side walls are connected to define a rectangular air duct, and a refrigeration sheet is attached to a side (i.e., the outer side) of each of the four side walls away from the air duct, and the refrigeration sheet is in close contact with a side of the side wall away from the air duct, so as to increase the contact area between the refrigeration sheet and the side wall, for achieving a good refrigeration effect.

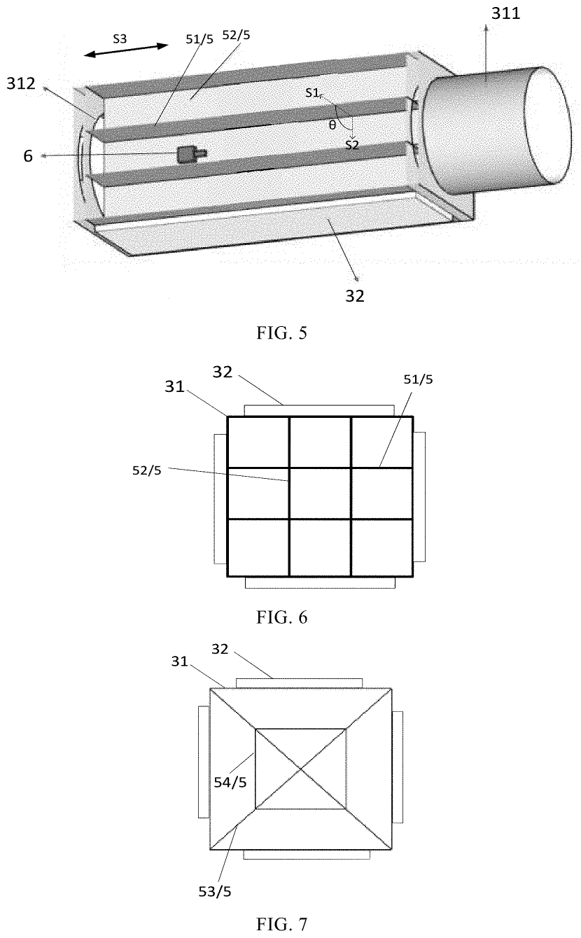

In some embodiments, the main body portion 31 defines an air duct in which at least one partition sheet 5 is disposed, and the partition sheet 5 separates the air duct into a plurality of sub-air ducts. That is, the partition sheet 5 and the side wall of the main body portion 31 define a sub-air duct, and the air duct is separated into a plurality of sub-air ducts. The extending direction of the partition sheet 5 is the same as the extending direction of the air duct, and the extending direction of the partition sheet 5 and the air duct is the length direction of the air duct (for example, the direction S3 in FIG. 5), so that the extending direction of the sub-air duct is the same as the air duct, and external air enters the air duct from the second air inlet 311 and then flows to the second air outlet 312 along the plurality of sub-air ducts.

In some examples, as shown in FIGS. 2, 5, and 6, FIG. 5 is an internal structure view of the main body portion 31 taken along a direction A-B in FIG. 2. The main body portion 31 defines an air duct in which a plurality of partition sheets 5 are disposed, and the plurality of partitions 5 can have various structures. For example, the plurality of partition sheets 5 are separated into a first partition sheet 51 and a second partition sheet 52. The plane of the first partition sheet 51 extends along the first direction S1, and if a plurality of first partition sheets 51 are provided, the plurality of first partition sheets 51 are parallel to each other. The plane of the second partition sheet 52 extends along the second direction S2 and if a plurality of second partition sheets 52 are provided, the plurality of second partition sheets 52 are parallel to each other. The first partition sheet 51 and the second partition sheet 52 are interpenetrated with each other, and the extending direction of the plane of the first partition sheet 51 (the first direction S1) intersects the extending direction of the plane of the second partition sheet 52 (the second direction S2). That is, the extending direction of the plane of the first partition sheet 51 (the first direction S1) and the extending direction of the plane of the second partition sheet 52 (the second direction S2) have an angle θ, and the angle θ is in the range of (0°, 90° ]. The intersecting first partition sheet 51 and second partition sheet 52 define sub-air duct. Referring to FIG. 6, taking the angle θ is 90°, i.e., the first partition sheet 51 are disposed perpendicularly to the second partition sheet 52, as an example, the first partition sheet 51 and the second partition sheet 52 are interpenetrated to form a four rectangle grid structure, so as to define a plurality of rectangular sub-air ducts, so that the air entering the inside defined by the main body portion 31 is exhausted more uniformly after passing through the plurality of sub-air ducts. It should be noted that the extending direction of the plane of the first partition sheet 51 or the second partition sheet 52 means that: a plane direction of the plane, in which the first partition sheet 51 or the second partition sheet 52 is located, with respect to the horizontal plane.

Alternatively, referring to FIG. 7, the partition sheet 5 in the air duct defined by the main body portion 31 can have other structures, for forming sub-air ducts with other shapes. For example, the air duct defined by the main body portion 31 is a rectangular air duct. A plurality of partition sheets 5 are disposed in the air duct defined by the main body portion 31, and the partition sheets 5 comprises two third partition sheets 53 and four fourth partition sheets 54. The length of each fourth partition sheet 54 is smaller than the side length of the rectangular air duct, and the four fourth partition sheets 54 are connected to form a small rectangular sub-air duct. The side length of each rectangular sub-air duct is smaller than the side length of the air duct defined by the main body portion 31. The rectangular sub-air duct is disposed in the center of the air duct defined by the main body portion 31, and the central axis of the rectangular sub-air duct coincides with the central axis of the air duct defined by the main body portion 31. The two third partition sheets 53 penetrate through the rectangular sub-air ducts and connect opposite corners of the rectangular air ducts respectively. That is, the two third partition sheets 53 are diagonal lines of the rectangular air duct (i.e., the inner wall of the main body portion 31) when viewed from the cross section of the main body portion 31. The specific structure of the partition sheet 5 in the air duct can also be various structures, which is not limited herein.

Alternatively, the side wall forming the main body portion 31 and the partition sheet 5 can be of an integral structure, or can be combined in a splicing connection manner. Taking that the side wall of the main body portion 31 and the partition sheet 5 are of an integral structure as an example, in the above embodiment of the partition sheet 5 comprising a first partition sheet 51 and a second partition sheet 52, wherein the first partition sheet 51, the second partition sheet 52 and the side wall of the main body portion 31 are of an integral structure. Alternatively, in the embodiment where partition sheet 5 comprises the third partition sheet 53 and the fourth partition sheet 54, wherein the third partition sheet 53, the fourth partition sheet 54, and the side wall of the main body portion 31 are of an integral structure.

In some examples, the side wall of the main body portion 31 and the partition sheet 5 are made of a heat conducting material. The heat conducting material includes multiple materials. For example, the heat conducting material can comprises silver, copper, gold, aluminum, silicon, graphene and combinations thereof. Such that, the sub-air duct or the side wall of the main body portion 31 has good thermal conductivity, and can conduct heat of air flowing through the sub-air duct to the temperature control component 32 (e.g., a semiconductor refrigeration sheet) outside the main body portion 31, thereby increasing heat transfer efficiency between the temperature control component 32 and the side wall of the main body portion 31.

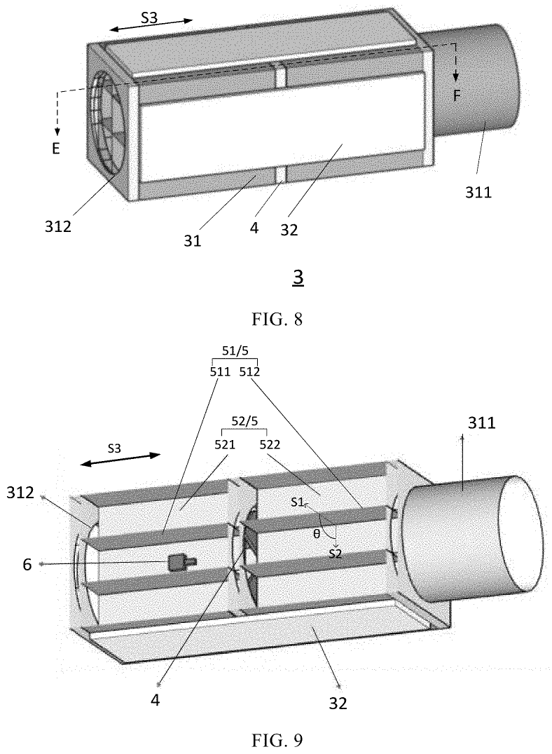

In some examples, as shown in FIG. 8, the temperature control structure 3 further includes a first fan 4, and the first fan 4 is disposed in the air duct defined by the main body portion 31. The first fan 4 provides power to drive air in the air duct to flow through the second air outlet 312 of the air duct 31 into the housing 2. In an embodiment without the first fan 4, the second air inlet 311 can blow air into the air duct by an external blowing device. The first fan 4 can be disposed at any position in the air duct, for example, at a middle position in the length direction of the air duct, or at either end of both ends of the air duct. The air duct can be provided with one first fan 4, or can be provided with a plurality of first fans 4, which is not limited herein.

In some examples, as shown in FIGS. 8 and 9, wherein FIG. 9 is an internal structure view taken along the direction E-F in FIG. 8. Taking that one first fan 4 is provided in the air duct defined by the main body portion 31 of the temperature control structure 3 as an example, if a partition sheet 5 is provided in the air duct defined by the main body portion 31, the partition sheet 5 is separated into two parts, and the first fan 4 is provided between the two parts. The main body portion 31 defines an air duct including a plurality of partition sheets 5, and the plurality of partition sheets 5 are separated into a first partition sheet 51 and a second partition sheet 52. A plane of the first partition sheet 51 extends in a first direction S1, a plane of the second partition sheet 52 extends in a second direction S2. The first partition sheet 51 and the second partition sheet 52 are interpenetrated with each other, and the extending direction of the plane of the first partition sheet 51 (the first direction S1) intersects the extending direction of the plane of the second partition sheet 52 (the second direction S2). Each of the first partition sheets 51 is separated into a first front partition sheet 511 and a first rear partition sheet 512 in a length direction (e.g., in a manner shown as S3 in FIG. 9), and each of the second separation sheets 52 is correspondingly separated into a second front partition sheet 521 and a second rear partition sheet 522 in the length direction. The plurality of first front partition sheets 511 and the plurality of second front partition sheets 521 are interpenetrated with each other, so as to form the front portion of the plurality of sub-air ducts. The plurality of first rear partition sheets 512 and the plurality of second rear partition sheets 522 are interpenetrated with each other, so as to form the rear portion of the plurality of sub-air ducts. The first fan 4 is disposed between the front portion and the rear portion of the sub-air duct. That is, the first fan 4 is disposed between the plurality of first front partition sheets 511 and the plurality of first rear partition sheets 512, and the first fan 4 is disposed between the plurality of second front partition sheets 521 and the plurality of second rear partition sheets 522. Depending on the position of the first fan 4 in the air duct defined by the main body portion 31, the first front partition sheet 511 and the first rear partition sheet 512 can have the same length or not, and the second front partition sheet 521 and the second rear partition sheet 522 can have the same length or not. For example, if the first fan 4 is disposed in the middle of the air duct defined by the main body portion 31, the first front partition sheet 511 and the first rear partition sheet 512 have the same length, and the second front partition sheet 521 and the second rear partition sheet 522 have the same length.

In some embodiments, further referring to FIGS. 8 and 9, the side wall of the main body portion 31 can also be separated into two parts: a first part forms an integral structure with a plurality of first front partition sheets 511 and a plurality of second front partition sheets 521, hereinafter referred to as “front part”; and a second part forms an integral structure with a plurality of first rear partition sheets 512 and a plurality of second rear partition sheets 522, hereinafter referred to as “rear part”. The first fan 41 is disposed between the front part and the rear part, the first fan 41 can be respectively bonded with the front part and the rear part, and then bonded with the temperature control component 32 (e.g., a semiconductor refrigeration sheet) disposed around the side wall, and the connection between the first fan 41 and the front part and the rear part is reinforced by the temperature control component 32.

In some examples, as shown in FIG. 9, the temperature control structure 3 further includes a first temperature sensor 6. The first temperature sensor 6 is disposed in the air duct defined by the main body portion 31 for detecting the temperature in the air duct, so as to prevent the air in the air duct from being too cold or too hot. Specifically, if the air duct defined by the main body portion 31 has partition sheet 5, the first temperature sensor 6 can be disposed on the partition sheet 5. If the partition sheet 5 is made of a heat conducting material, the partition sheet 5 has a good thermal conductivity. The first temperature sensor 6 is in contact with the partition sheet 5, so that the environment temperature in the air duct, that is, the temperature of the partition sheet 5 and the air in the air duct, can be accurately detected.

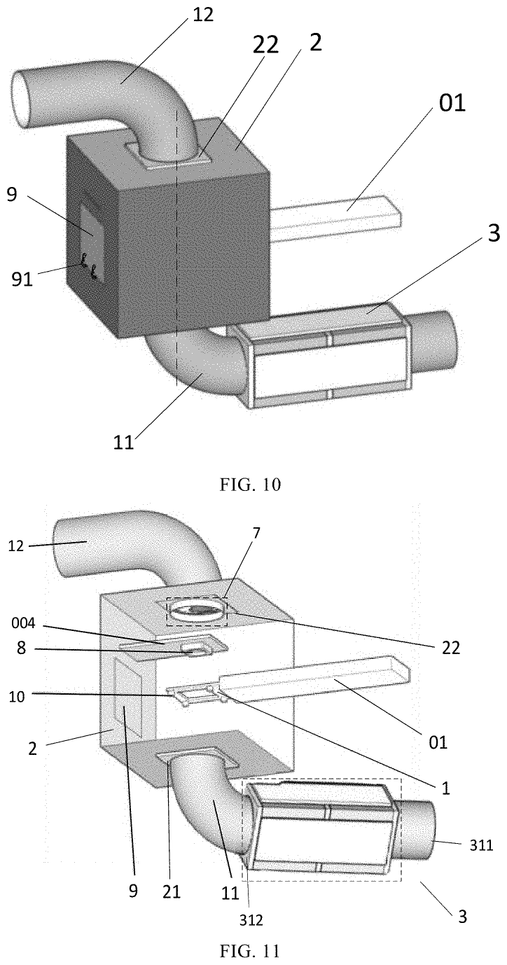

In some examples, as shown in FIGS. 10 and 11, FIG. 11 is a schematic diagram of an internal structure of the temperature control device. The temperature control device further comprises an air outlet channel 12 and an air inlet channel 11. The air outlet channel 12 is connected to the first air outlet 22 of the housing 2. The air inlet channel 11 is connected between the first air inlet 21 of the housing 2 and the second air outlet 312 of the main body portion 31 of the temperature control structure 3. The external air enters the air duct defined by the main body portion 31 from the second air inlet 311 of the main body portion 31 of the temperature control structure 3, and enters air inlet channel 11 by the second air outlet 312 of main body portion 31 after being cooled, and then enters the housing 2 through the first air inlet 21 of housing 2, and cools the chip disposed on the object stage 1 in the housing 2, and then enters air outlet channel 12 by the first air outlet 22 of housing 2 and then discharges to the outside.

In some examples, as shown in FIGS. 10 and 11, the air outlet channel 12 and the air inlet channel 11 can be straight passage or curved passage. For convenience of description, taking the air outlet channel 12 and the air inlet channel 11 in FIG. 10 as curved passages as an example, the air outlet channel 12 and the air inlet channel 11 are connected to opposite sides of the housing 2. In the figure, taking the air outlet channel 12 connected to an upper side of the housing 2, and the air inlet channel 11 connected to a lower side of the housing 2 as an example, the air inlet channel 11 is a C-shaped curved passage. One end of the air inlet channel 11 is connected to the first air inlet 21 at the lower side of the housing 2, and the other end extends in a direction facing away from the housing 2. The air outlet channel 12 is a C-shaped curved passage, one end of the air outlet channel 12 is connected to the first air outlet 22 on the upper side of the housing 2, and the other end extends in the direction facing away from the housing 2. The air inlet channel 11 and the air outlet channel 12 extend in opposite directions relative to the central axis of the housing 2, and the center of the cross-section of the end of the air inlet channel 11 connected to the housing 2 coincides with the center of the cross-section of the end of the air outlet channel 12 connected to the housing 2. The above is merely an example of the structure of the air outlet channel 12 and the air inlet channel 11, which is not limited herein.

In some examples, as shown in FIG. 11, at least one second fan 7 is disposed at the first air outlet 12. After the air is sent into the housing 2 through the cooling of the at least one temperature control structure 3 to cool the chip on the object stage 1, the second fan 7 is used to exhaust the wind in the housing 2 to the outside of the housing 2, so as to accelerate the ventilation efficiency in the housing 2.

In some examples, as shown in FIG. 11, the temperature control device further includes a second temperature sensor 8. The second temperature sensor 8 is disposed in the housing 2, and the second temperature sensor 8 is disposed close to the object stage 1. Specifically, the second temperature sensor 8 can be fixed in position by using a fixing member 004. One end of the fixing member 004 is connected to the inside of the housing 2, and the other end of the fixing member 004 extends to directly above the object stage 1. The second temperature sensor 8 is fixed at the side of the other end of the fixing member 004 close to the object stage 1, so that the second temperature sensor 8 can detect the temperature of the chip on the object stage 1 to accurately obtain the temperature of the chip. The temperature of the chip on the object stage 1 in the housing 2 is adjusted according to the obtained temperature of the chip. The second temperature sensor 8 is a non-contact temperature sensor. The distance between the second temperature sensor 8 and the chip can be adjusted by adjusting the position of the fixing member 004. The smaller the distance between the second temperature sensor 8 and the chip is, the more accurate the detected temperature is. For example, the distance between the second temperature sensor 8 and the chip is 1 cm.

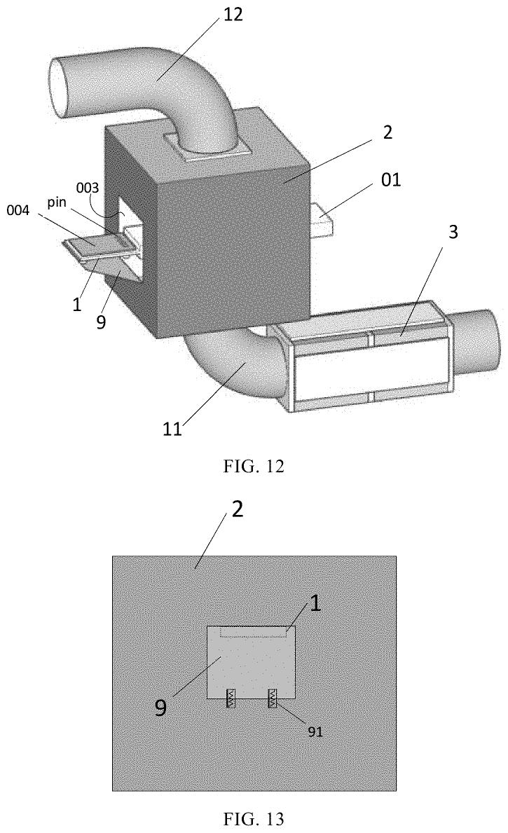

In some examples, as shown in FIGS. 10-13, the housing 2 has an opening 003 at a position corresponding to the object stage 1, and a loading valve 9 is disposed at the opening 003. Referring to FIG. 12, the loading valve 9 has a first end and a second end opposite to each other, and the first end is taken as a lower end and the second end is taken as an upper end in the figure for illustration. The opening 003 in the housing 2 has one side and the other side opposed to each other, and the one side is taken as a lower side and the other side is taken as an upper side in the figure for illustration. The lower end of the loading valve 9 is rotatably connected to the lower side of the opening 003, and the lower end of the loading valve 9 is rotated around the lower side of the opening 003 to open or close the loading valve 9. Specifically, when the loading valve 9 is in a closed state (as shown in FIG. 10), the upper end of the loading valve 9 contacts the upper side of the opening 003 (i.e., closed), so as to seal the housing. When the loading valve 9 is in an open state (as shown in FIG. 12), the object stage 1 can protrude outside the housing 2 through the opening 003, which facilitates chip replacement.

The opening 003 can have any shape, such as a rectangular opening and a circular opening. In this embodiment, the opening 003 is a rectangular opening as an example for description.

Alternatively, referring to FIGS. 10 and 13, FIG. 13 is a side view of the housing 2 pointing from one side of the loading valve 9 to the opposite side of the loading valve 9. The end of the loading valve 9 rotatably connected to the opening 003 has a connection structure 91, and the connection structure 91 is connected to the lower end of the loading valve 9 and the lower side of the housing 2 close to the opening 003, so as to maintain the closed state of the loading valve 9. The connection structure 91 has elasticity. Taking the connection structure 91 as a spring lock as an example, when the object stage 1 extends out of the housing 2, the object stage 1 abuts against the loading valve 9, and the connection structure 91 is compressed to open the loading valve 9; when the object stage 1 moves into the housing 2, the connection structure 91 automatically restores the deformation, and the loading valve 9 is closed by using the restoring force of the spring. The connecting structure 91 can also be other types of locking devices, which is not limited herein.

Alternatively, referring to FIGS. 10-13, the position of the upper side of the opening 003 on the outer side of the housing 2 is higher than or equal to the position of the plane of the object stage 1, and the width of the opening 003 is greater than the width of the object stage 1, so as to ensure that the object stage 1 can extend out of the housing 2 from the opening 003. The area of the loading valve 9 is greater than or equal to the area of the opening 003, and the upper end of the loading valve 9 can be equal to or higher than the position of the plane of the upper side of the opening 003.

In some examples, further referring to FIG. 13, when the loading valve 9 is in the closed state, the upper end of the loading valve 9 is not higher than the plane of the object stage 1. Specifically, the upper end of the loading valve 9 is not higher than the plane of the upper surface of the object stage 1. Such that, when the object stage 1 abuts against the loading valve 9 to extend out of the housing 2 (as shown in FIG. 12), the object stage 1 is not obscured by the upper end of the loading valve 9, thereby facilitating chip replacement.

It should be noted that the upper end of the loading valve 9 can also be higher than the plane of the object stage 1, which is not limited herein, as long as the object stage 1 can contact the loading valve 9, so that the object stage 1 can abut against the loading valve 9 to push the loading valve 9 open. For convenience of description, the upper end of the loading valve 9 is not higher than the plane of the object stage 1 in the present embodiment, which is not limited herein.

In some examples, referring to FIG. 1, the housing 2 can further have an inlet valve 005, and the inlet valve 005 is disposed opposite to the loading valve 9. The object stage 1 enters the housing 2 through the inlet valve 005, and then extends out of the housing 2 through the loading valve 9 to load the chip 004.

In some examples, further referring to FIG. 12, the chip 004 is placed on the object stage 1, and the chip 004 has a plurality of first pins. A plurality of connectors (not shown) are provided on a side of the object stage 1 contacting the chip 004, and the connectors are connected to an external power source. After the chip 004 is loaded on the object stage 1, the first pins and the connectors are in one-to-one connection, and the external power source powers on the chip 004 through the connectors, so that the chip 004 starts heating up. The connector can comprise various types of connectors, such as a resilient tab connector. A terminal of the resilient tab connector is connected to an external power source through a connection line, and the other end of the resilient tab connector is in contact with first pins of the chip 004, so as to transmit a voltage to the chip 004.

In some examples, referring to FIG. 11, a plurality of spring knobs 10 are disposed on the opposite side of the side of the object stage 1 carrying the chip (i.e. the lower side of the object stage 1 in the figure). After the chip is detected, the detection result needs to be read, the fixing arm 01 is driven by an external force to move the object stage 1 out of the housing 2 and then move the object stage onto an external platform. The spring knobs 9 are used to adjust the inclination angle of the object plane (i.e. the plane carrying the chip) of the object stage 1 relative to the external platform (e.g. the observation platform of the microscope), so that the object plane of the object stage 1 is parallel to the lens of the microscope, and the object stage 1 is prevented from being inclined to the lens of the microscope and thus causing the chip observed by the microscope to appear as an inclined plane. It should be noted that the angle range of the inclination angle of the object plane of the object stage 1 with respect to the external platform is not limited. If the object plane of the object stage 1 is parallel to the plane of the external platform, the inclination angle of the object plane of the object stage 1 with respect to the external platform is 0°.

In some examples, the object stage 1 can be a rectangular object stage. The opposite side of the side of the object stage 1 carrying the chip can be provided with four spring knobs 10, and the four spring knobs 10 are respectively disposed at four corners of the rectangular object stage 1. The stage 1 can be an object stage having other shapes, such as a circular shape, a hexagonal shape and the like, and the stage 1 can have any number of spring knobs 10, which is not limited herein.

In a second aspect, an embodiment of the present disclosure further provides a temperature control system, wherein the temperature control system includes the above temperature control device.

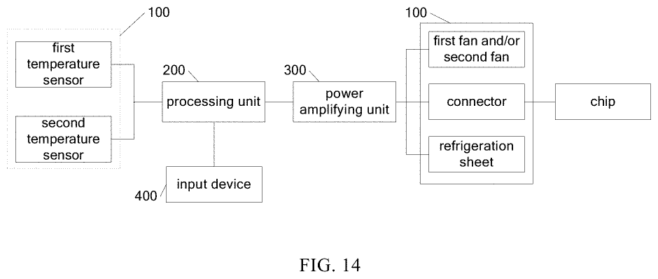

In some examples, referring to FIG. 14, the temperature control system can further comprise a processing unit 200, a power amplifying unit 300, and an input device 400. The input device 400 is connected to the processing unit 200, and the processing unit 200 sends a control instruction to the temperature control device 100 according to an operation instruction input by the input device 400, so as to control the temperature control device 100 to adjust the temperature. The power amplifying unit 300 is connected between the processing unit 200 and the temperature control device 100, and is configured to output a control voltage to the temperature control device according to a control instruction sent by the processing unit.

Further referring to FIG. 14, taking the temperature control device 100 as an example, the temperature control device 100 can specifically comprise a housing, an object stage, and a cooling structure. The object stage is located in the housing. At least one second fan is disposed at a first air outlet of the housing, and the second fan is configured to exhaust air in the housing to the outside. A second temperature sensor is also disposed in the housing at a position close to the object stage, and the second temperature sensor is configured to detect a temperature of a chip on the object stage. The object stage is provided with a plurality of connectors, and if the chip is loaded on the object stage, the connectors and the first pins on the chips are in one-to-one connection. The cooling structure comprises a temperature control component and a main body portion, and the main body portion defines an air duct. In this embodiment, temperature control component as a refrigeration sheet is taken as an example. The refrigeration sheet is disposed to tightly attach to the outer wall of the main body portion. The air duct defined by the main body portion is provided with a partition sheet, so as to separate the air duct into a plurality of sub-air ducts. The partition sheet is provided with a first temperature sensor, and the first temperature sensor is used to detect the temperature inside the air duct. The air duct is also provided with a first fan, and the first fan is used for sending air in the air duct into the housing.

The operation principle of the temperature control system is described by taking the above temperature control device 100 as an example. For convenience of description, only the first temperature sensor, the second temperature sensor, the first fan, the second fan, the connector and the refrigeration sheet of the temperature control device 100 are shown in FIG. 14.

Specifically, the input device 400 is connected to the processing unit 200, and a user can input various operation instructions to the processing unit 200 by operating the input device 400. Taking that the chip is a dPCR chip and the detection process requires multiple temperature cycles as an example, the operating instructions can be, for example, an instruction to start a system, an instruction to set a temperature of a temperature cycle, an instruction to set a time of the temperature cycle, an instruction to set a cycle number of the temperature cycle, and the like. The processing unit 200 has a plurality of input interfaces and output interfaces. The input interfaces are connected to the input device 400, the first temperature control sensor, the second temperature control sensor, and the like. The output interfaces are connected to the power amplifying unit 300, the power amplifying unit 300 is connected to the first fan, the second fan, the connector, the refrigeration sheet, and the like. The power amplifying unit 300 outputs a control voltage according to a received control signal sent by the processing unit 200, and outputs the control voltage to a corresponding one of the first fan, the second fan, the connector, and the refrigeration sheet. According to an operation instruction input by the input device 400, the processing unit 200 can output a control instruction, such as a start control instruction to turn on or off the first fan and/or the second fan. The processing unit 200 has a memory and a pulse generator. A pre-set temperature adjustment algorithm is stored in the memory. After receiving the temperature information in the air duct input by the first temperature sensor, the processing unit 200 can output a control instruction (specifically, a power control instruction) to the refrigeration sheet according to the pre-set temperature adjustment algorithm, so as to the refrigerating power of the refrigerating sheet can be adjusted, and such that the temperature in the air duct can be adjusted. Moreover, after receiving the temperature information of the chip on the object stage input by the second temperature sensor, the processing unit 200 can output a control instruction (specifically, a voltage control instruction) to the connector according to a pre-set temperature adjustment algorithm, so as to adjust the voltage output by the connector to the first pin of the chip, and such that adjust the temperature of the chip.

It should be noted that the above control instruction, such as a start control instruction for turning on or off the first fan and/or the second fan, a power control instruction, and a voltage control instruction, can be Pulse Width Modulation (PWM) signals, and are output by a Pulse generator of the processing unit 200. The connector, the refrigeration sheet, the first fan and the second fan are all connected to the power amplifying unit 300. The power amplifying unit 300 comprises a pulse width modulation switch. Since the PWM signal output by the processing unit 200 is a weak current signal and cannot provide working voltage for the temperature control device, after receiving the PWM signal output by the pulse generator of the processing unit 200, the pulse width modulation switch outputs corresponding control voltage according to the PWM signal. The pulse width of the control voltage is the same as (or approximately the same as) the pulse width of the PWM signal output by the processing unit 200, but the voltage (amplitude) is greater than the PWM signal, so that the pulse width modulation switch outputs the control voltage to the connector, the refrigeration sheet, the first fan and the second fan, and therefore the working voltage can be provided for the connector, the refrigeration sheet, the first fan and the second fan.

In some examples, the input device 400 can comprise multiple types of input devices. For example, the input device 400 can be a touch screen. It should be noted that, the input device 400 is not limited to the touch screen, and is not limited herein. If the input device 400 is a touch screen, the touch screen can display operation keys, and can also display the temperature information detected by the first temperature sensor and the second temperature sensor, the information of the chip, and the like in real time.

In some examples, the processing unit 200 can comprise various types of control boards. For example, the processing unit 200 can be an Arduino development board, which is not limited herein.

In some examples, the temperature control system can further comprise a moving device (not shown). The moving device is connected to the object stage. Specifically, the moving device is connected to an end of the fixing arm facing away from the object stage. The moving device controls the fixing arm to move so as to drive the object stage to move, and then can drive the chip on the object stage to move so as to extend out of the housing or return into the housing. When the temperature control system provided by the embodiment of the present disclosure performs chip detection, taking that the chip is a dPCR chip and the detection process requires multiple temperature cycles (i.e., heating, cooling, and heating) as an example for description, the detection process can include the following steps:

S1 loading the chip.

Specifically, the moving device controls the object stage 1 to move to the loading valve 9 and abut against the loading valve 9, so as to open the loading valve 9, and the object stage 1 is further extended out of the housing 2 from the opening 003, and the chip 004 is placed on the object stage 1 (from FIG. 10 to the state shown in FIG. 12). The moving device then controls the object stage 1 to move back into the housing 2, and the loading valve 9 is automatically closed by the driving of the connecting structure 91 (from FIG. 12 to the device shown in FIG. 10).

Optionally, the pre-detection of temperature control structure 3 can be performed, so as to ensure that the refrigeration power of temperature control structure 3 can meet the required cooling demand of detection. Specifically, the temperature control component 32 (e.g., a refrigeration sheet) is activated while the first temperature sensor 6 obtains temperature information in the air duct defined by the main body portion 31 in real time. According to the obtained temperature information of the air duct, it is determined whether the refrigeration power of the temperature control component 32 meets the required cooling demand of detection. If the refrigeration power does not meet the cooling demand, the adjustment is then being performed. If the refrigeration power has met the cooling demand, then completing the pre-detection of the temperature control structure 3.

It should be noted that the step of performing the pre-detection on the temperature control structure 3 can be performed before the chip is loaded, or can be performed simultaneously during the loading process of the Chip (i.e., S1). If loading the chip and detecting the temperature control structure 3 are performed simultaneously, the chip detection time can be reduced, and the chip detection efficiency can be improved.

S2 Detecting under the temperature control of the temperature control device.

Firstly, after the chip is placed on the object stage 1, the first pin of the chip is electrically connected to the second pin on the object stage, and the chip starts heating up after being powered on. Meanwhile, the second temperature sensor 8 obtains the temperature information of the chip in real time, the heating power of the chip is determined according to the temperature information of the chip, so as to ensure the chip heats up to reach the temperature required by detection and maintain the required time. The process is completed in the housing 2, and therefore, the housing 2 can isolate the thermal environment between the chip and the external environment, so that the chip can accurately heat up to the required temperature and maintain the required time.

Then, after the time length of the chip maintaining the heated temperature reaches the required time length, the chip stops being powered on, and the first fan 4 and the second fan 7 are activated. The first fan 4 guides external air into an air duct defined by the main body portion 31 of the temperature control structure 3, the cooled air is sent into the housing 2, so as to cool the chip. The second fan 7 extracts the air in the housing 2 to achieve cooling circulation, and the second temperature sensor 8 obtains the temperature of the chip in real time. When the temperature of the chip is quickly reduced to the required low-temperature, the first fan 4 and the second fan 7 are turned off, and the chip is powered on, and after the temperature of the chip is maintained for the required time length, the chip then heats up. After the heating times required by the chip detection are completed by repeating the above steps, stopping powering on the chip to complete the detection.

It is to be understood that the above embodiments are merely exemplary embodiments adopted to illustrate the principles of the disclosed embodiments, and that the disclosed embodiments are not limited thereto. It will be apparent to those skilled in the art that various modifications and improvements can be made without departing from the spirit and scope of the embodiments of the present disclosure, and such modifications and improvements are also considered to be within the scope of the embodiments of the present disclosure.

1. A temperature control device for controlling the temperature of a chip detection process, comprising:
a object stage for carrying the chip;
a housing provided with a first air inlet and a first air outlet, the object stage is disposed in the housing, and the housing is used for reducing heat transfer between the chip on the object stage and an external environment;
at least one temperature control structure provided with a main body portion and a temperature control component, and the main body portion defines an air duct;
wherein the main body portion is provided with a second air inlet and a second air outlet, the second air outlet is connected to the first air inlet, and external air enters the air duct defined by the main body portion from the second air inlet and then enters the housing from the second air outlet; the temperature control component is connected to the main body portion to control the temperature of the air in the air duct.

2. The temperature control device of claim 1, wherein the temperature control component is a cooling component or a heating component.

3. The temperature control device of claim 1, wherein the temperature control component comprises at least one refrigeration sheet disposed on a side of the main body portion away from the air duct.

4. The temperature control device of claim 3, wherein the main body portion has at least one side wall defining the air duct; if the main body portion is provided with a plurality of side walls, the refrigeration sheets are in one-to-one correspondence with the side walls, and each refrigeration sheet is attached to a side of the corresponding side wall away from the air duct.

5. The temperature control device of claim 3, wherein the refrigeration sheet comprise a semiconductor refrigeration sheet, and the semiconductor refrigeration sheet has a refrigeration surface on a side of the semiconductor refrigeration sheet close to the main body portion and a heat dissipation surface on a side of the semiconductor refrigeration sheet away from the main body portion; the heat dissipation surface is connected with a heat dissipation structure, and the heat dissipation structure is used for cooling the heat dissipation surface.

6. The temperature control device of claim 1, wherein at least one partition sheet is disposed within the air duct defined by the main body portion, the partition sheet separating the air duct into a plurality of sub-air ducts; the extending direction of the separating sheet is the same as the extending direction of the air duct.

7. The temperature control device of claim 6, wherein a plurality of the partition sheets are disposed in the air duct defined by the main body portion, and the plurality of the partition sheets are separated into first partition sheets and second partition sheets; wherein,
the plane of the first partition sheet extends along a first direction, the plane of the second partition sheet extends along a second direction, and the first partition sheet and the second partition sheet are interpenetrated with each other, and the extending direction of the plane of the first partition sheet intersects the extending direction of the plane of the second partition sheet.

8. The temperature control device of claim 6, wherein the side wall of the main body portion and the partition sheet are of an integral structure.

9. The temperature control device of claim 6, wherein the side wall of the main body portion and the partition sheet are made of thermally conductive material.

10. The temperature control device of claim 1, wherein the temperature control structure further comprises: a first fan disposed in the air duct defined by the main body portion, and the first fan is used for sending air in the air duct into the housing.

11. The temperature control device of claim 7, wherein each of the first partition sheets is divided into a first front partition sheet and a first rear partition sheet in a length direction; each of the second partition sheet is separated into a second front partition sheet and a second partition sheet in the length direction;
the temperature control structure further comprises: a first fan disposed between the plurality of first front partition sheets and the plurality of first rear partition sheets, and the first fan is disposed between the plurality of second front partition sheets and the plurality of second rear partition sheets.

12. The temperature control device according to claim 1, wherein the temperature control structure further comprises: a first temperature sensor disposed in the air duct defined by the main body portion, and the first temperature sensor is used for detecting the temperature in the air duct.

13. The temperature control device of claim 1, wherein at least one second fan is disposed at the first air outlet, and the second fan is used for exhausting the air inside the housing to the outside.

14. The temperature control device of claim 1, further comprising:
an air outlet channel connected with the first air outlet, and an air inlet channel connected between the first air inlet and the second air outlet; wherein,
the air outlet channel and the air inlet channel are connected to the opposite sides of the housing, and the air outlet channel and the air inlet channel extend along opposite directions relative to the central axis of the housing.

15. The temperature control device of claim 1, wherein the housing has an opening at a position corresponding to the object stage, the housing has some distance from the object stage, and a loading valve is disposed at the opening;
the loading valve has opposite first and second ends; the first end of the loading valve is rotatably connected to one side of the opening, and when the loading valve is in a closed state, the second end of the loading valve is in contact with the other side of the opening so as to seal the housing; when the loading valve is in an open state, the object stage can extend out of the housing through the opening.

16. The temperature control device of claim 15, wherein the second end is not higher than the plane of the object stage when the loading valve is in a closed state.

17. The temperature control device of claim 1, further comprising: a second temperature sensor disposed in the housing, and the second temperature sensor is disposed close to the object stage, and the second temperature sensor is used for detecting the temperature of the chip on the object stage.

18. The temperature control device of claim 1, wherein a plurality of spring knobs are disposed on the opposite side of the side of the object stage carrying the chip, and if the object stage is placed on an external platform, the spring knobs are used for adjusting the inclination angle of the plane of the object stage carrying the chip relative to the external platform.

19. A temperature control system comprising the temperature control device of claim 1.

20. The temperature control system of claim 19, further comprising:
a processing unit;
an input device connected to the processing unit, the processing unit sends a control instruction to the temperature control device according to an operation instruction input by the input device so as to control the temperature control device to adjust the temperature; and
a power amplifying unit connected between the processing unit and the temperature control device, and the power amplifying unit is used for outputting control voltage to the temperature control device according to the control instruction sent by the processing unit.
